(19) United States
(12) Patent Application Publication
(10) Pub. No.: US 2007/0001771 A1
(43) Pub. Date: Jan. 4, 2007

(54) Oscillation circuit

(75) Inventors: Chikahiro Hori, Yokohama-Shi (JP); Akira Takiba, Kawasaki-Shi (JP); Masanori Kinugasa, Yokohama-Shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/476,554

(22) Filed: Jun. 29, 2006

(30) Foreign Application Priority Data
Jun. 30, 2005 (JP) 2005-191668

(51) Int. Cl. H03K 3/03

(52) U.S. Cl. 331/57

(57) ABSTRACT

An oscillation circuit comprises a ring oscillator configured to have at least an odd number of stages of inverters, and a frequency multiplier section configured to output as a multiplied output, an exclusive OR of signals taken out from the inverters at least at two stages of the ring oscillator.

### CROSS REFERENCE TO RELATED APPLICATION

This application claims benefit of priority under 35 USC §119 to the Japanese Patent Application No. 2005-191668, filed on Jun. 30, 2005, and the entire contents of which are incorporated by references herein.

### BACKGROUND

The present application relates to an oscillation circuit and, more particularly, to an oscillation circuit having a multiplied output.

Conventionally, accurately generating a double frequency is not impossible, but requires much effort at the time of designing. In a ring oscillator that is often used as an oscillator, the oscillation period is proportional to the number of stages of inverters constituting the oscillator. However, the number of stages of inverters is odd, and can not be equally halved. In many oscillators that are realized by a simple ring oscillator, a bias circuit is used to compensate various environmental conditions, and hence, these oscillators are realized by redesigning a portion for producing a clock. However, since the various conditions are related to each other, the oscillators can not be simply redesigned. In this way, in the conventional oscillation circuit, a technique for making it possible to simply multiply the frequency has not been proposed, and hence, the doubling of a capacity of a memory such as an Electrically Erasable and Programmable Read Only Memory (hereinafter abbreviated as an EEPROM) has been coped by doubling the scale of the booster circuit.

Therefore, as a prior art of the oscillation circuit having multiplied outputs, an oscillation circuit which independently outputs a clock of the oscillation circuit, and which generates and outputs plural multiplied clocks, has not been proposed. However, as the latest preceding techniques, there are proposed a multiplying circuit disclosed in Japanese Patent Laid-open No. 5-218821 (1993), a logic circuit disclosed in Japanese Patent Laid-open No. 9-294058 (1997), and a duty ratio adjustable multiplier disclosed in U.S. Pat. No. 5,963,071 and the like. In any of the preceding techniques, there is disclosed a circuit configuration in which an oscillator itself does not output a ring oscillator output and plural multiplied clocks, but which is formed by combining the oscillation circuit with multiplying means or doubling means.

As described above, in the conventional oscillation circuit, it is difficult to accurately produce a clock with a multiplied frequency, and the clock can not be accurately multiplied. Further, in the case where the area of a booster circuit cooperating with a clock generating mean is multiplied in accordance with the size of the memory, a problem arises that goes against space-saving requirements.

### SUMMARY

An oscillation circuit according to an embodiment comprises a ring oscillator configured to have at least an odd number of stages of inverters, and a frequency multiplier section configured to output as a multiplied output, an exclusive OR of signals taken out from the inverters at least at two stages of the ring oscillator.

### BRIEF DESCRIPTION OF THE DRAWINGS

FIG. 1 is a circuit diagram showing, as a basic principle, an oscillation circuit according to a first embodiment;

FIG. 2 is a block diagram showing a configuration of an EEPROM to which the oscillation circuit is applied;

FIG. 3 is a more specific circuit diagram showing an oscillation circuit according to a second embodiment;

FIG. 4 is a block diagram showing a configuration of a part of a memory unit in which the configuration shown in FIG. 3 is used;

FIG. 5 is a waveform of each node of the circuit shown in FIG. 3;

FIG. 6 is a circuit diagram showing an oscillation circuit according to a third embodiment;

FIG. 7 is a circuit diagram showing an oscillation circuit according to a fourth embodiment;

FIG. 8 is a block diagram showing a configuration of a part of a memory unit in which the configuration shown in FIG. 7 is used;

FIG. 9 is a circuit diagram showing an oscillation circuit according to a sixth embodiment;

FIG. 10 is a block diagram showing a configuration of a part of a memory unit in which the configuration shown in FIG. 9 is used;

FIG. 11 is a waveform of the voltage detector used in the sixth embodiment;

FIG. 12 is a block diagram showing a configuration of a part of a memory unit in which the seventh embodiment is used;

FIG. 13 is a circuit diagram showing a configuration of an oscillation circuit according to an eighth embodiment;

FIG. 14 is a characteristic diagram showing waveforms of each node of the circuit in FIG. 13;

FIG. 15 is a circuit diagram showing a configuration of an oscillation circuit according to a ninth embodiment;

FIG. 16 is a characteristic diagram showing waveforms of each node and waveforms of the outputs in FIG. 15;

FIG. 17 is a block diagram showing a configuration of an oscillation circuit according to a tenth embodiment; and

FIG. 18 is a circuit diagram showing a configuration of a charge pump circuit as a booster circuit.

### DETAILED DESCRIPTION OF THE EMBODIMENTS

In the following, embodiments of the oscillation circuit will be described in more detail with reference to the drawings.

### First Embodiment

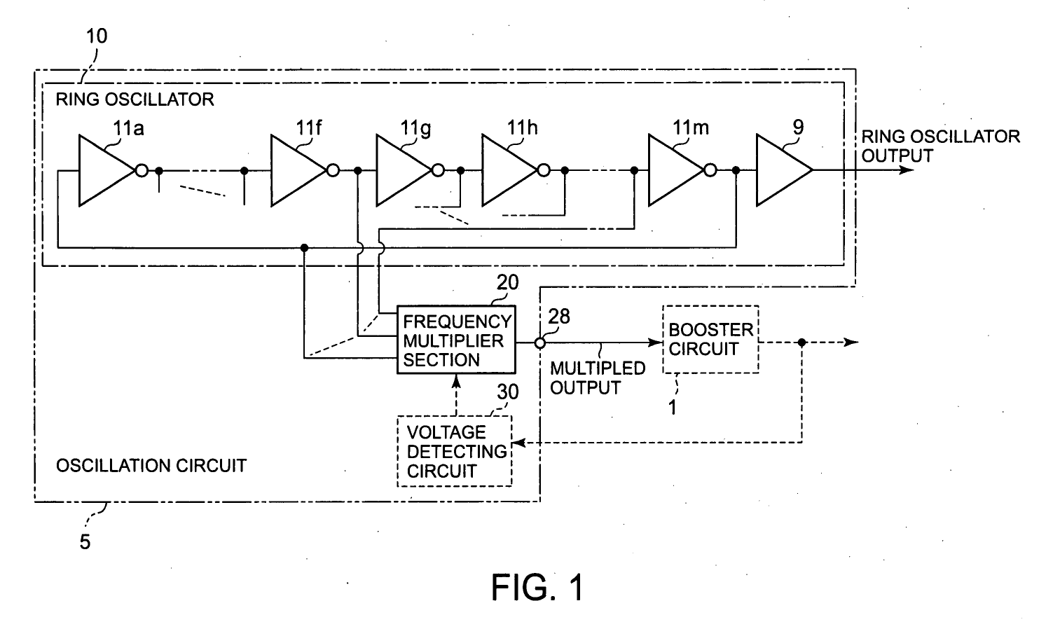

A first embodiment including a fundamental configuration is explained using FIG. 1. In the block diagram shown in FIG. 1, an oscillation circuit 5 is provided with a ring oscillator 10 which includes an odd number of stages of inverters 11a to 11m, and with a frequency multiplier section 20 which outputs an exclusive OR (hereinafter abbreviated as an EOR) of two signals as a multiplied output to a clock terminal 28, which two signals are taken out from outputs of the inverters at least at two stages in the ring oscillator 10, for example, the outputs of the inverter of the final stage 11m and the inverter of the approximately intermediate stage 11f.

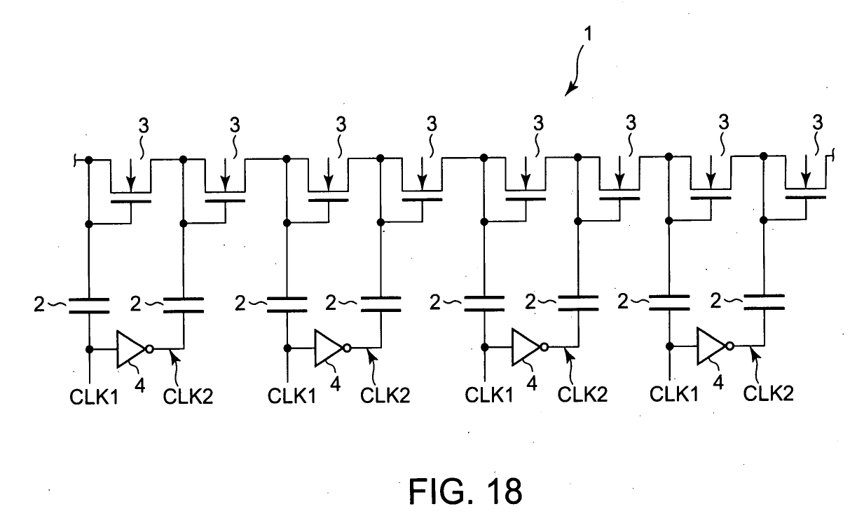

In the ring oscillator 10 configured as described above, an output is successively formed by the first stage inverter 11a to the final stage inverter 11m, and is finally outputted as the output of the ring oscillator 10 via a buffer 9. The frequency multiplier section 20 operates exclusive OR of outputs from the inverters, for example, an output of exclusive OR of an output of the inverter 11m of the final stage and an output of the inverter 11f at the preceding stage of the inverter of the intermediate stage 11g, and outputs the output of exclusive OR to a booster circuit 1 such as a charge pump circuit as will be described below with reference to FIG. 18, via the clock terminal 28. In this way, the oscillation circuit according to the first embodiment is an oscillation circuit which has the output of the ring oscillator 10, and a doubled output, in other words, a multiplied output. Note that since the ring oscillator 10 is configured by an odd number of stages of inverters 11m, it is impossible to lead out the output of the inverter at the exactly middle stage, and hence, the node behind the inverter 11g which is the intermediate stage, or node in front of the inverter 11g that is the output of the inverter 11f, can be used.

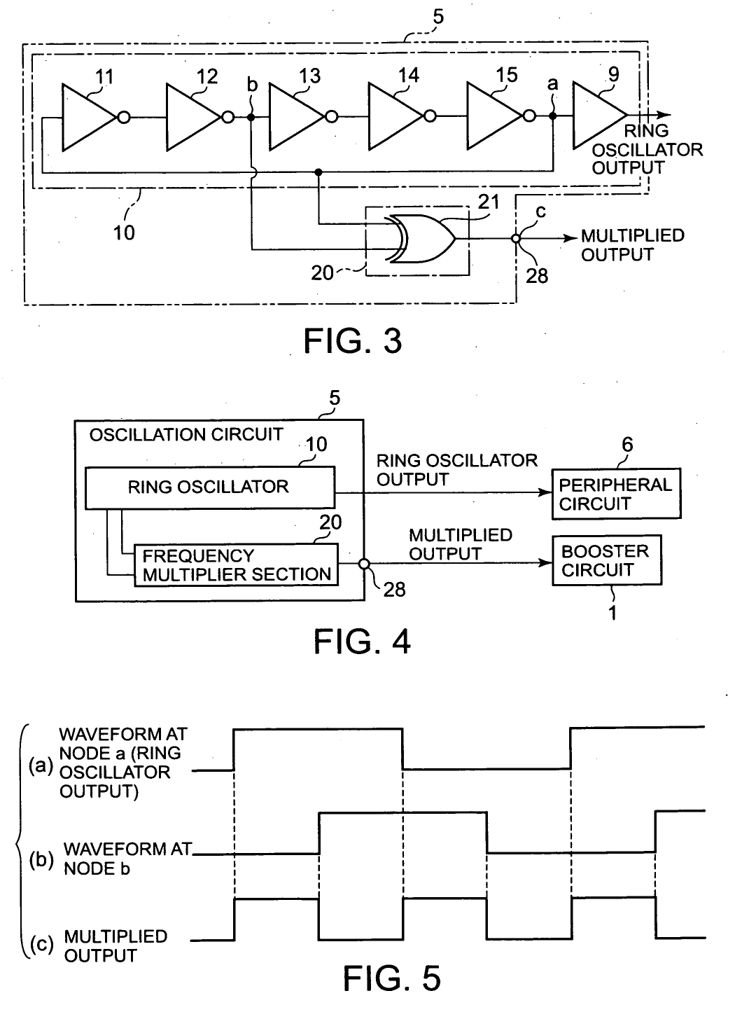

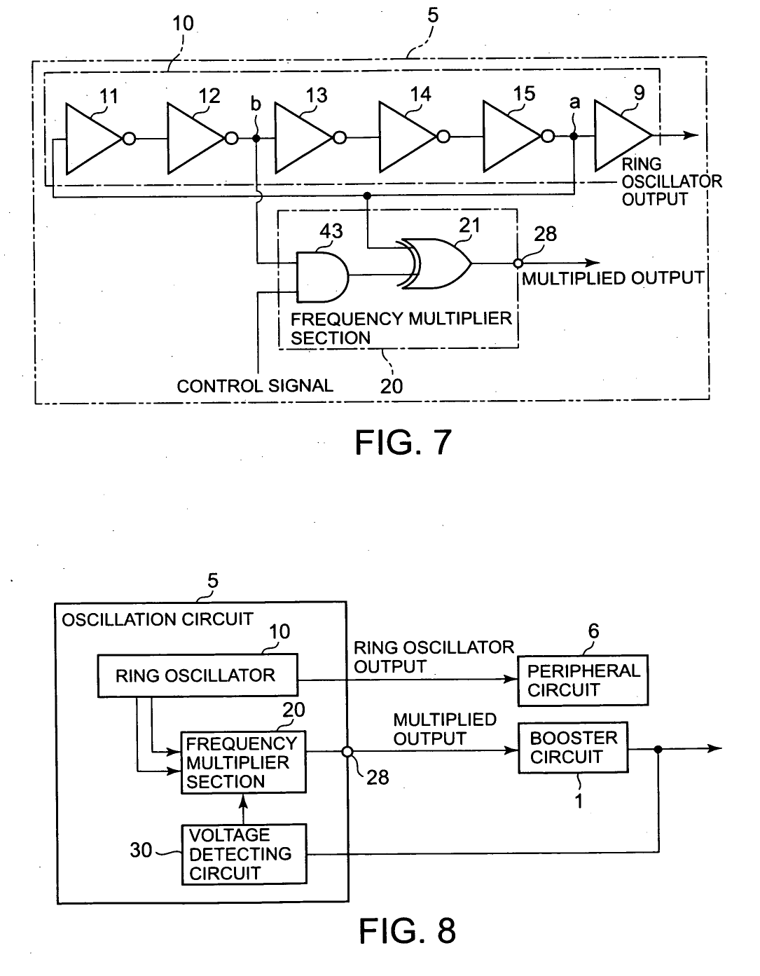

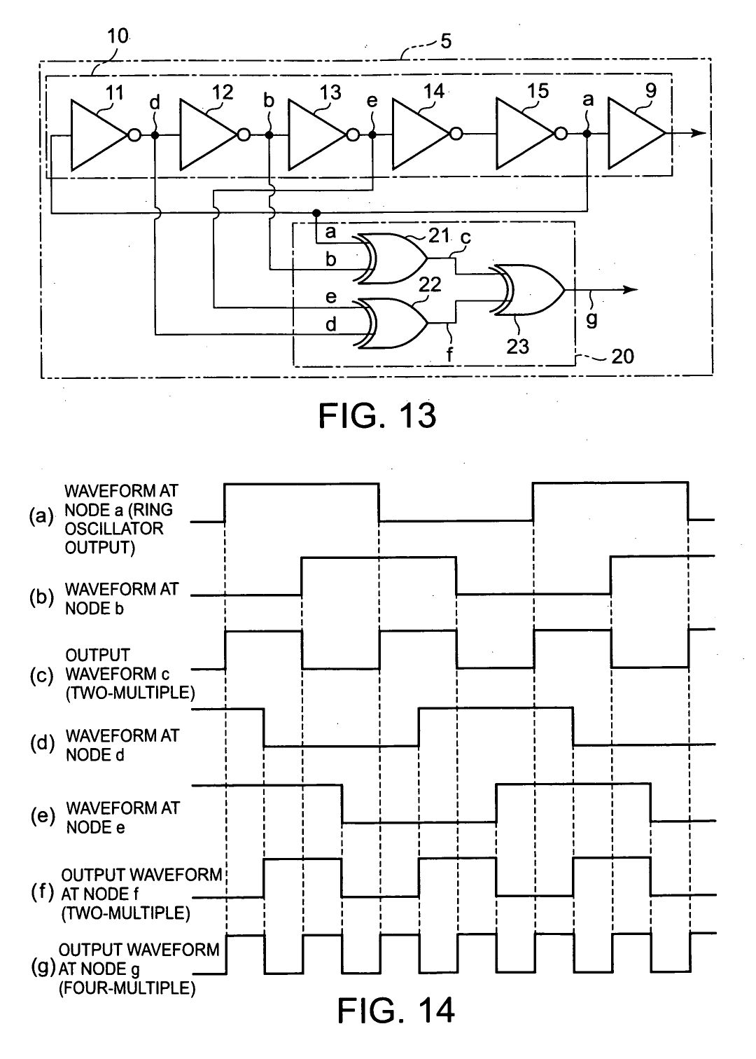

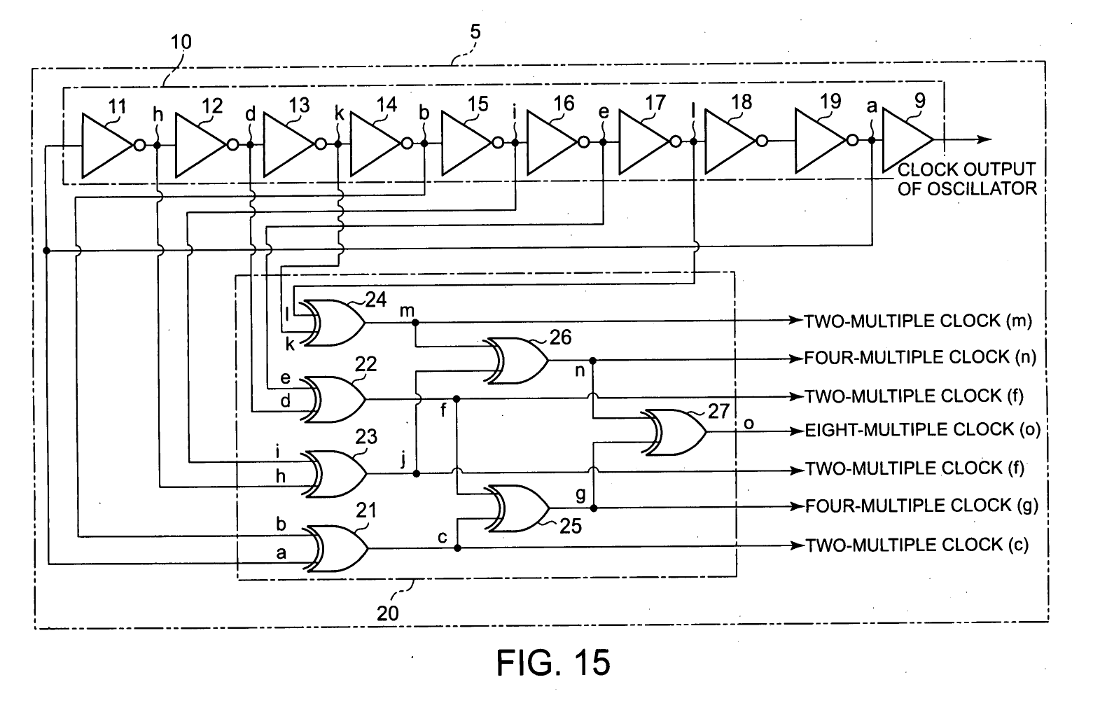

As will be described in detail in second and subsequent embodiments, the frequency multiplier section 20 may be configured to be provided with a logic circuit for taking an exclusive OR of the two signals taken out from the inverters at arbitrary stages. Further, the frequency multiplier section 20 may be provided with a first logic circuit (see FIG. 3 as will be described below) which outputs a two-multiple clock by an exclusive OR circuit, a second logic circuit (see FIG. 13 as will be described below) which outputs a four-multiple clock by three exclusive OR circuits, and a third logic circuit (see FIG. 15 as will be described below) which outputs an eight-multiple clock by seven exclusive OR circuits. The frequency multiplier section 20 may also be provided with one of these logic circuits, for example, the first logic circuit. Further, as shown in FIG. 7 as will be described below, the frequency multiplier section 20 may be provided as an exclusive OR device which receives the two signals from the two inverter stages and a control signal, and which outputs one of the two signals according to the control signal. Further, the frequency multiplier section 20 may be arranged to receive a multiplied clock outputted by the exclusive OR device, and to operate an exclusive OR according to a control signal from a voltage detecting circuit 30 which outputs the control signal in relation to the boosted voltage.

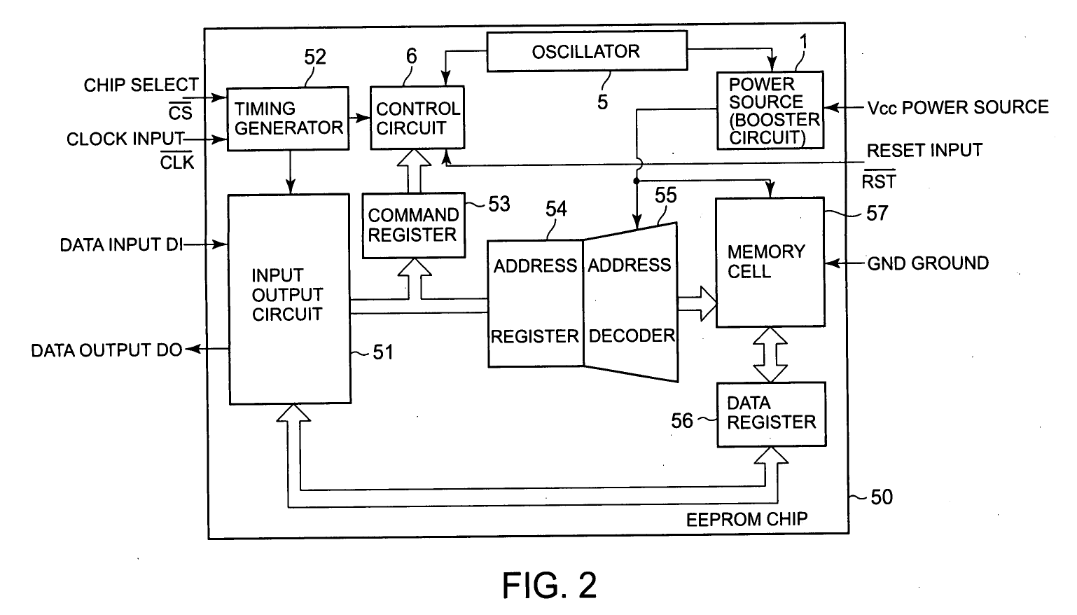

Note that the oscillation circuit 5 shown in FIG. 1 is formed on an EEPROM chip 50 as shown in FIG. 2. In FIG. 2, the EEPROM chip 50 is provided with a high voltage power supply (booster circuit) 1 which receives a Vcc power supply and boosts the received voltage, an oscillator 5 having the configuration as shown in FIG. 1, and a control circuit 6 as one of peripheral circuits. A ring oscillator output of the oscillator 5 according to the present application is supplied to the control circuit 6, and the multiplied clock, which is used to generate a high voltage, is supplied to the booster circuit 1. In addition, the EEPROM 50 is provided with an input output circuit 51, a timing generator 52, a command register 53, an address register 54, an address decoder 55, a data register 56, a memory cell 57, and the like. Note that the high voltage generated by the booster circuit 1 is supplied not only to the address decoder 55, but also to the memory cell 57 and other components. In this way, the oscillation circuit of the first embodiment shown in FIG. 1, which has the multiplied output, is arranged in the EEPROM chip 50 as shown in FIG. 2, and used.

Generally, in the nonvolatile memories as represented by the EEPROM, a high voltage power source is needed to write or to erase the data.

In the EEPROM, the writing/erasing operation is performed by rejecting/injecting the electron through a tunnel oxide film to a floating gate by the high voltage. On the other hand, at the time of reading operation is performed by a normal voltage.

In order to generate the high voltage for writing into the EEPROM, a charge pump circuit 1 as shown in FIG. 18 is used in many cases. The charge pumping circuit 1 is provided with a configuration as shown in FIG. 18, and is configured by capacitors 2, diodes (or metal oxide semiconductor (MOS) transistors connected to be diodes) 3, and inverters 4. The charge pump circuit 1 makes electric charges moving to the capacitor 2, just like a pump by supplying a first clock CLK 1 and a second clock CLK 2 as an inverted signal of the first clock. When an electric charge Q is accumulated in a capacitor having a capacitance C, a voltage V determined by Q/C (V=Q/C) is generated. Thus, the high voltage can be obtained by continuously transferring electric charges 2 by using the charge pump circuit 1. In the case of an EEPROM, which charges/discharges electric charges by using the tunnel current, current is consumed at the time of the writing/erasing operation. The necessary voltage can be maintained by keeping the capability of the electric charge transferring at the level of the current consumption or beyond.

Meanwhile, the storage capacity of a memory, in particular a nonvolatile memory, typically increases in a power of two. Thereby, when a new product with a large memory capacity is added to a series of memory products, it is necessary to double the memory capacity. The maximum current required at the time of writing/erasing operation is naturally double, so that the boosting capability in the booster circuit also needs to be doubled.

For improving the boosting capability of the charge pump circuit, the following two methods are conceivable. The first method is to increase the circuit scale and the second method is to increase the clock frequency. Conventionally, in order to improve the boosting capability of the charge pump circuit, the first method, that is, increasing the circuit scale has been used. This is because that the second method for doubling the clock frequency is difficult to be realized due to the problems as described below. And the problem is much serious than a disadvantage of the increase of the chip area required to double the circuit size of the booster circuit in order to double the boosting capability in accordance with the doubling of the memory capacity.

It is possible to double the clock frequency itself. However, there is a special situation in order to double the clock frequency in the booster circuit of an EEPROM. When a memory cell is doubled, the clock frequency also needs to be almost accurately doubled. Further, there is also a requirement that the output of the same clock frequency as the conventional one being left. In the case of a circuit such as an EEPROM in which the tunnel oxide film is used, when the clock frequency is excessively increased, it causes a stress to be applied to the tunnel oxide film. As a result, when the memory capacity is doubled, the exactly doubled boosting capability is needed. In many cases, the oscillator supplies the clock frequency not only to the booster circuit but also to the peripheral circuit of the memory. However, there is also a requirement that the clock supplied to the peripheral circuit be the same as the frequency for memories with other capacities, in terms of the line-up of the products. In the case of a digital circuit, the frequency can be easily divided into +E,frac 1/2, and hence, if a frequency is accurately doubled, it is acceptable for this requirement. However, it is preferred that the same clock as the conventional one is supplied.

Preferably, the MOS transistor forming an inverter in the ring oscillator, which the gate is connected with a signal line taking out to the frequency multiplier section, is configured to have a low product (W×L) of width (W) and length (L) in comparison with the MOS transistors forming other inverters. More preferably, the ring oscillator is configured to have a short length (L) in comparison with the MOS transistors forming other inverters.

For example, in the ring oscillator 10 as shown in FIG. 1, when signals which are taken out to the frequency multiplier section 20 are outputs of the inverters 11f and 11m, MOS transistors forming the inverters 11g and 11a are configured to have a low W×L, especially a short L in comparison with the MOS transistors forming other inverters. In second to tenth embodiments as will be described, in the same manner of the first embodiment, it is possible to accurately maintain a frequency of the ring oscillator by forming a MOS transistor to have a low W×L especially a short L constructing the inverters which are respectively connected with the inverters for supplying signals to the frequency multiplier section 20.

### Second Embodiment

A second embodiment is described. FIG. 3 is a circuit diagram showing an oscillation circuit having a multiplied output according to the second embodiment. FIG. 4 shows a block diagram in the case where the oscillation circuit is used in FIG. 2. As shown in the left side of FIG. 4, an oscillation circuit 5 is configured by a ring oscillator 10 and a frequency multiplier section 20. More specifically, as shown in FIG. 3, the oscillation circuit 5 is configured so as to be provided with the ring oscillator 10 configured by a first to fifth inverters 11, 12, 13, 14, 15 and a buffer 9, and with the frequency multiplier section 20 configured by an exclusive OR circuit 21 which receives two signals of the output of the fifth inverter 15 and the output of the second inverter 12, and which outputs an exclusive OR of the two signals.

The second embodiment shown in FIG. 3 is configured in such a manner that the circuit shown in the figure outputs an oscillation output of the ring oscillator 10 and an output formed by doubling the oscillation output by the exclusive OR circuit 21, and that the circuit also supplies the doubled output to a booster circuit 1 and the ring oscillator output to a peripheral circuit 6, as shown in FIG. 4. In the case of FIG. 3, it is possible to double the frequency of the clock supplied to the booster circuit 1 without changing the frequency of the oscillation output supplied to the peripheral circuit 6, so that the operation speed of the booster circuit 1 supplied with the doubled clock is accurately doubled and thereby the doubled boosting capability can be obtained.

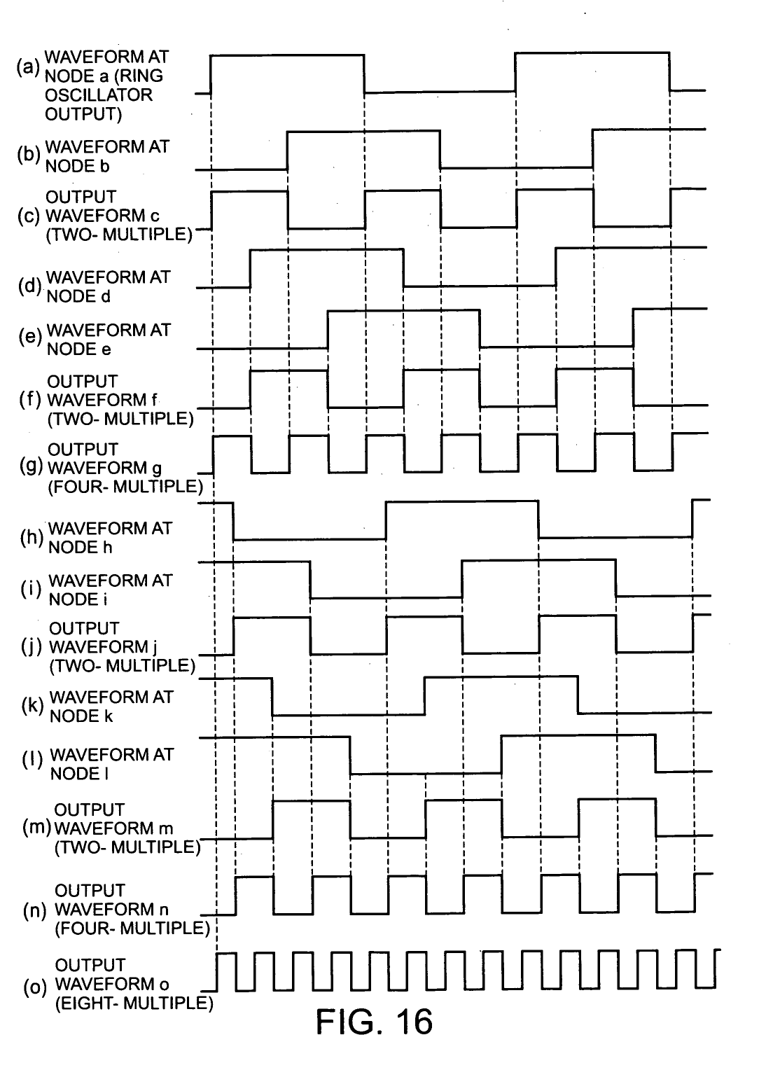

FIG. 5 shows signal waveforms at a node a, a node b and a doubled output c in the oscillation circuit shown in FIG. 3, respectively. The waveform of the signal at the node a in FIG. 5, which signal passes through the buffer 9 so as to be the output of the ring oscillator 10, is almost equal to the waveform of the output of the ring oscillator. The waveform at the node b is delayed by almost a half period from the waveform at the node a, but has a frequency almost the same as the frequency of the signal at the node a. The output of the exclusive OR circuit 21 is set at the low level during the period in which the signal levels at the nodes a, b are equal, while the output of the exclusive OR circuit 21 is set at the high level during the period in which the signal levels at the nodes a, b are different each other, as a result of which a clock having a frequency twice that of the ring oscillator output is outputted as shown in FIG. 5 (C). Note that in FIG. 5, FIG. 14, FIG. 16 which show waveforms at the output nodes of the inverters in the oscillation circuit configured by the odd number of stages of inverters, the node a is the output node of the inverter of the final stage, the node b is the output node of the inverter of an approximately intermediate stage, but the other nodes are output nodes of arbitrary inverters depending upon the number of inverters and are the nodes shown in FIG. 3, FIG. 13, FIG. 15, respectively.

The oscillator circuit having the multiplied output described here, has two oscillation outputs which include the oscillation output of the ring oscillator 10, and the oscillation output obtained by performing EOR (exclusive OR) of the internal signals of the ring oscillator 10. The latter output which has a frequency twice that of the former output, is led to the booster circuit 1, while the former output is led to the peripheral circuit 6. In the case of the second embodiment, the EOR oscillation output is obtained by exactly doubling the ring oscillator oscillation output, and hence, the clock frequency supplied to the booster circuit 1 can be doubled without changing the frequency supplied to the peripheral circuit 6.

In the second embodiment, an element additionally provided in order to obtain doubled clock frequency is only the EOR logic gate 21. Therefore, when the embodiment is introduced into a semiconductor chip, only a component with a very small circuit size needs to be added. Further, the EOR circuit is a digital circuit, which has an advantage that a fine adjustment is not needed in designing the circuit, and the circuit can also be easily designed. Further, according to the configuration described above, it is possible to double the memory capacity without increasing the circuit size of the booster circuit. Another advantage of the second embodiment is that the frequency can be easily changed.

Even in the second embodiment, preferably, the MOS transistor forming an inverter in the ring oscillator, which the gates are connected with a signal line to be supplied to the frequency multiplier section, are configured to have a low product (W×L) of width (W) and length (L) in comparison with the MOS transistors forming other inverters. More preferably, the MOS transistors are configured to have a short length (L) in comparison with the MOS transistors forming other inverters.

For example, in the ring oscillator 10 as shown in FIG. 3, when a signal which is taken out to the EOR circuit 21 is outputs of the inverters 12 and 15, MOS transistors forming the inverters 13 and 11 are configured to have a low W×L, especially a short L in comparison with the size of MOS transistors forming other inverters. In this manner, it is possible to accurately maintain a frequency of the ring oscillator by forming a MOS transistor to have a low W×L especially a short L constructing the inverters which are respectively connected with the inverters for supplying signals to the EOR circuit 21 (the frequency multiplier section 20).

An ordinary ring oscillator uses inverters each having a fixed size, so that nodes a, b connected to the EOR circuit 21 have large capacitive load of the EOR circuit 21 in comparison with the other inverters in the ring oscillator 10. Since the capacitive load is not large so much and a drop of a frequency by this load is not large, it is ordinarily possible to ignore the capacitive load. However, in the specific cases of the large number of signals taken out from the ring oscillator 10 to the EOR circuit 21 or the like, it is impossible to ignore the capacitive load. In such cases, it is effective to regulate the capacitance by making a size of the MOS of the inverters 13 and 11 each succeedingly connected to the inverters 12 and 15 which supply the signal to the EOR circuit 21.

Since the capacitance of the MOS inverter is substantially in proportion to W×L of the transistor as a component, the capacitance of the MOS inverter can be reduced by reducing W×L. However, the driving force of the MOS inverter is proportional to W/L, the regulation of the capacitance by only reducing W×L may make the driving force of the inverter be reduced. Even though a low W×L makes the capacitance be reduced, a low W×L may also make W/L be low and the driving force of the inverter be reduced to cause operation to be delayed.

Accordingly, in case of the reduction of W×L, reducing L without W/L is effective to avoid the drop of the frequency in two effects, one is the reduction of the capacitance of the inverter and the other is the increase of the driving force of the inverter. Of course, it is also effective to reduce L of the transistor with reducing W in the same ratio.

Third Embodiment

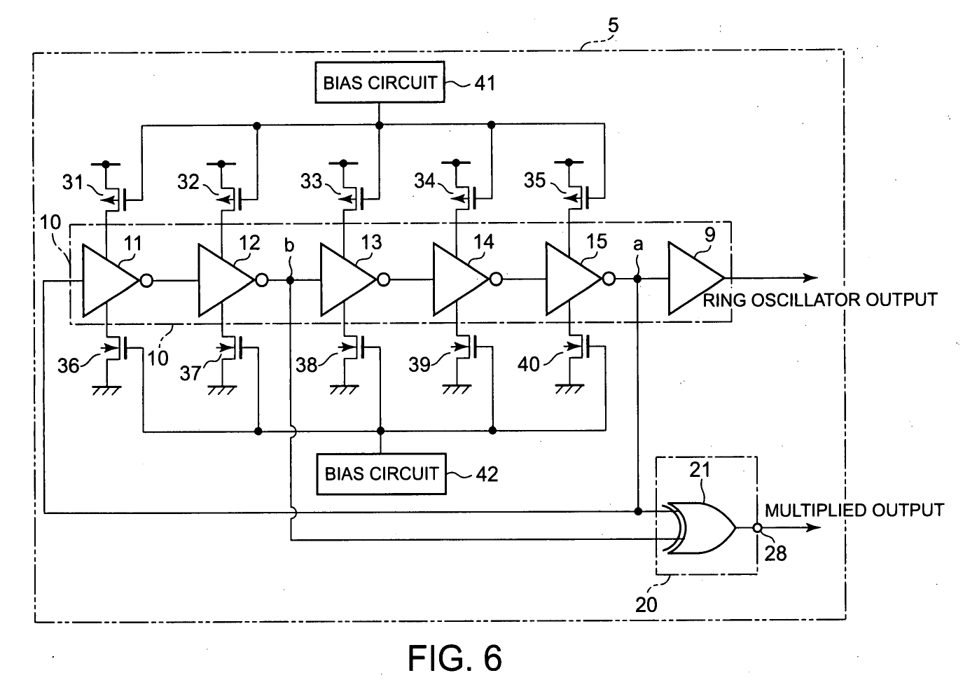

Next, an oscillation circuit according to a third embodiment is described. In the third embodiment, a ring oscillator 10 is not a simple configuration like the second embodiment as shown in FIG. 3. This embodiment is configured, as shown in FIG. 6, in such a manner that P-channel as a first conductive type metal-oxide semiconductor (MOS) transistors 31, 32, 33, 34, 35 are provided for a high voltage side power source for a first to fifth inverters 11, 12, 13, 14, 15, that N-channel MOS transistors 36, 37, 38, 39, 40 are provided for a low voltage side power source, and that an EOR circuit 21 as a frequency multiplier section 20 and a clock terminal 28 for multiplied output are provided. In the oscillation circuit 5 having a ring oscillator 10 which stabilizes its oscillation frequency according to a signal from a first bias circuit 41 that supplies a bias signal to the gate of the MOS transistors 31 to 35, and a signal from a second bias circuit 42 that supplies a bias signal to the gate of the MOS transistors 35 to 40.

In the circuit diagram of the third embodiment shown in FIG. 6, the exclusive OR circuit 21 takes exclusive OR of respective waveforms of a node “a” and a node “b”, so that the multiplied output which appears at the terminal 28 has a frequency twice that of the ring oscillator output. The third embodiment is capable of stabilizing the ring oscillator output of the ring oscillator 10 by supplying the bias signal to the gates of the MOS transistors 31 to 35 and the gates of the MOS transistors 36 to 40 from the bias circuits 41, 42, and is also capable of stabilizing the multiplied output of the EOR gate 21.

A characteristic configuration of the oscillation circuit 5 according to the third embodiment is that the MOS transistors 31 to 40 and the first and second bias circuits 41, 42, are provided. Since other configuration is further the same as that of the second embodiment shown in FIG. 3 and the operational waveforms at the respective nodes are also the same as those shown in FIG. 5.

Meanwhile, in the same manner of the first and second embodiments, it is effective to make the MOS transistors forming the inverters 13 and 11 have a low W×L especially a short L in comparison with the size of the MOS transistors of the inverters 12, 14 and 15.

### Fourth Embodiment

Next, a fourth embodiment is described. As explained as the further advantage of the second embodiment, according to the present application, the frequency can be easily changed. The EOR circuit is a logic circuit, and hence, is easily configured by the addition of a control line so as to output the oscillation output of the ring oscillator itself, instead of the EOR output. By turning on and off the control line, it is possible to instantly set the frequency supplied to the booster circuit 1 to be doubled or to a normal frequency. Further, as in the case of the fifth embodiment as will be described below, by adding another control line, the output can be set to a fixed value, that is, the clock can also be stopped. There still exists an oscillator which is capable of oscillating at plural oscillation frequencies, but in most cases, such oscillator needs a certain amount of time to stabilize the oscillation state after an oscillation frequency is switched to the next.

According to the described configuration, since the function of EOR needs only to be changed in a digital manner, the signal waveform may only be deformed in one clock period before and after the switching. Subsequent to this period, the clock can be outputted without any problem in the waveform. Further, in the case where the clock signal is used for the booster circuit, the waveform deformation caused during the one clock period only makes the charge pump inactive during this period, and hence, the disturbance scarcely influences the boosted voltage. Therefore, the switching of the frequency at high speed is very effective to the changing of the boosting capability.

FIG. 7 and FIG. 8 show an oscillation circuit according to a fourth embodiment. In FIG. 7, the EOR gate of the second embodiment is replaced by an EOR function block with a control function. In the circuit of the EOR function block, as shown in FIG. 7, a frequency multiplier section 20 is provided with an exclusive OR gate 21 and an AND (logical product) gate 43. In the fourth embodiment, an oscillation circuit 5 is further provided with a voltage detecting circuit 30 which detects a boosted voltage of a booster circuit 1, as shown in the block diagram of FIG. 8. The voltage detecting circuit 30 has a hysteresis characteristic. In the case where the boosted voltage is increased, when the boosted voltage is not higher than a first predetermined voltage, an output value of a control signal is set to 1 and when the boosted voltage is higher than the predetermined voltage, the output value of the control signal is set to 0. In the case where the boosted voltage is decreasing, the output value of the control signal is set to 0 until the boosted voltage is decreasing to reach a second predetermined voltage, and when the voltage reaches the predetermined value, the output value of the control signal is set to 1. As a result, when the boosted voltage is higher than the first predetermined voltage, the multiplication of the oscillation frequency is stopped, and thereby the increase of the boosted voltage is reduced or the boosted voltage is reduced. The size of the circuit for discharging the electric charges when the voltage is excessively boosted can be reduced introducing this embodiment. On the contrary, when the detected voltage becomes lower than the first predetermined voltage, the boosting capability is increased by multiplying the oscillation frequency so as to prevent defective writing/erasing operations.

Meanwhile, in the same manner of the first through third embodiments, it is effective to make the MOS transistors forming the inverters 13 and 11 have a low W×L especially a short L in comparison with the size of the MOS transistors of the inverters 12, 14 and 15.

Fifth Embodiment

The voltage detecting circuit 30 described in the fourth embodiment is arranged to set the control signal to 0 or 1 on the basis of the detected voltage. On the other hand, in a fifth embodiment (not shown), the output of the voltage detecting circuit is frequently and repeatedly changed to 0 or 1, and hence, the period during which the output of the voltage detecting circuit is 0 or 1 is changed according to the detected voltage. More specifically, when the voltage is high, the period during which the output is 0 is set to be long. On the other hand, when the voltage is low, the period during which the output is 1 is set to be long. Thus, it is possible to perform fine control of the boosted voltage by arranging for the ratio of such periods to be slowly changed according to the detected voltage.

Meanwhile, in the same manner of the first through fourth embodiments, it is effective to make the MOS transistors forming the inverters which are succeedingly connected to the inverters to supply the signals to the frequency multiplier circuit 20 have a low W×L especially a short L in comparison with the size of the MOS transistors of other inverters.

### Sixth Embodiment

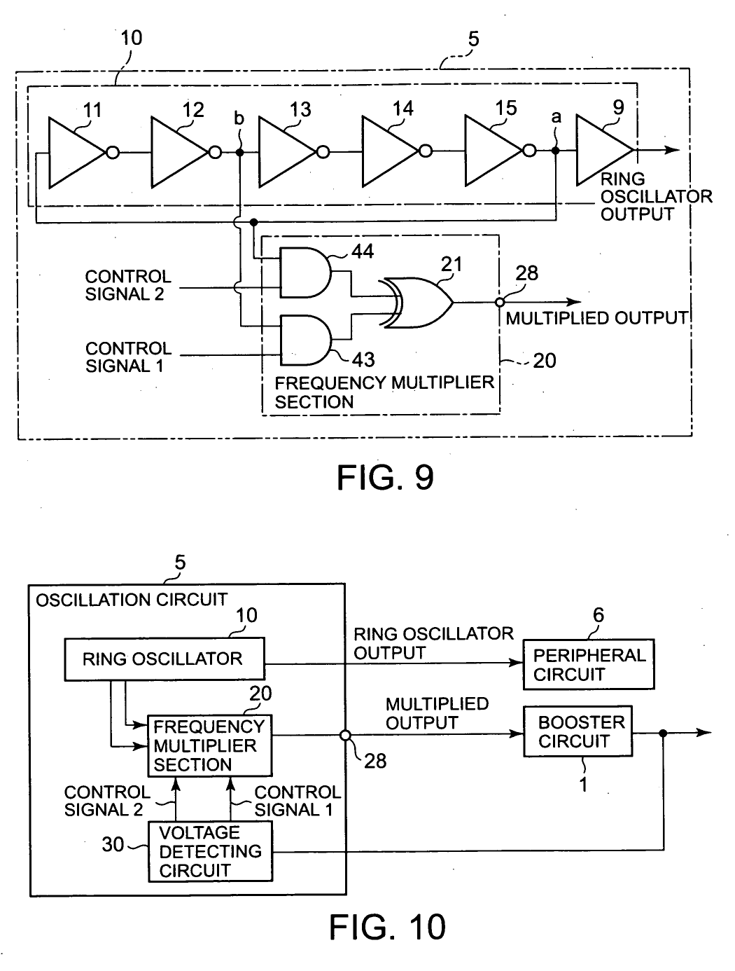

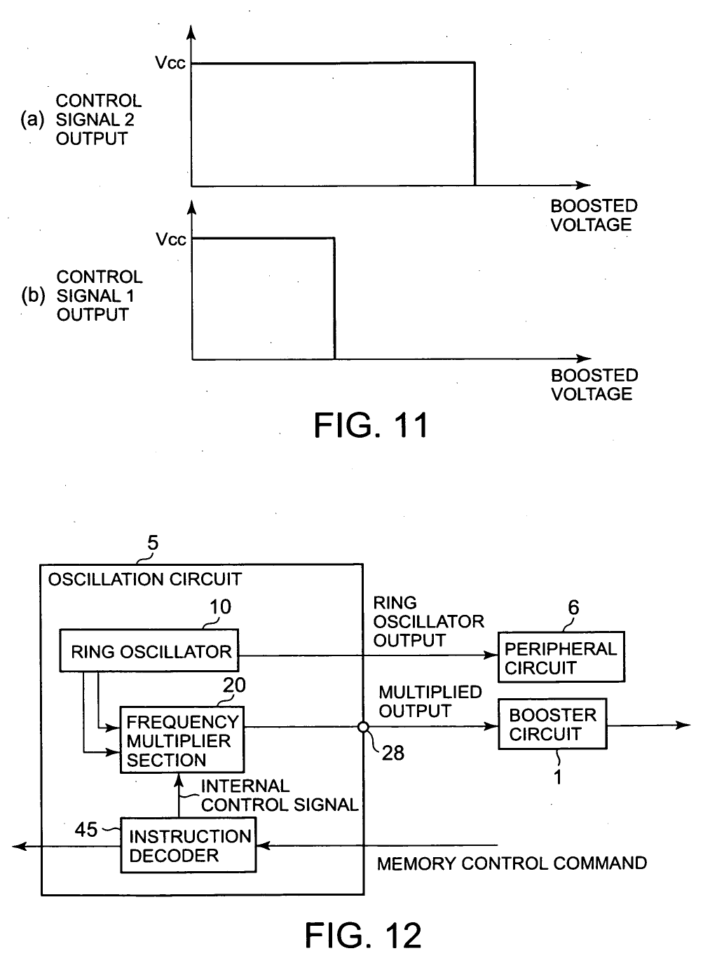

FIG. 9, FIG. 10, FIG. 11 are a circuit diagram, a block diagram, and a characteristic diagram for explaining the oscillation circuit according to a sixth embodiment, respectively. In FIG. 9, an AND (logical product) circuit 44 is added to the configuration of the frequency multiplier section 20 as the EOR function block of the fourth embodiment, and another control line is added to the one control line of the fourth embodiment, so that the output of the EOR logic circuit is fixed by this second control line. Specifically, this logic gate is provided with an AND gate 43 which performs the logical AND of the output of the inverter 12 and the control signal 1, an AND gate 44 which performs the logical AND of the output of the inverter 15 of the final stage and the control signal 2, and an EOR gate 21 which performs an EOR of the outputs of the AND gates 43 and 44.

In the sixth embodiment, the voltage detecting circuit in FIG. 10 generates a control output in accordance with the boosted voltage as shown in FIG. 11. Thereby, when the boosted voltage is a low voltage, the multiplied clock is supplied to the booster circuit 1, and when the boosted voltage becomes a relatively high voltage, the multiplying function is stopped and the boosting capability is reduced. When the boosted voltage becomes a still higher voltage, the voltage boosting operation is stopped by fixing the clock signal supplied to the booster circuit 1. Thereby, it is possible to eliminate the conventionally required circuit which discharges electric charges at the time of excessive boosting. This is due to the fact that current required for writing/erasing function is consumed at the time of writing/erasing operation and various kinds of leakage current also flow, and hence, the output voltage of the booster circuit is continuously lowered from the time point when the clock of the booster circuit is stopped.

Meanwhile, in the same manner of the first through fifth embodiments, it is effective to make the MOS transistors forming the inverters 13 and 11 have a low W×L especially a short L in comparison with the size of the MOS transistors of the inverters 12, 14 and 15.

### Seventh Embodiment

FIG. 12 is a block diagram showing a configuration of a seventh embodiment. An oscillation circuit 10 in the seventh embodiment is that used in the third embodiment and shown in FIG. 7. In the block of the oscillation circuit, an instruction decoder 45 interprets an instruction from the outside and generates an internal control signal. In this block, when the instruction is decoded, it is determined whether a large amount of current is needed or not in the writing/erasing operation. For example, the instruction to erase all bits needs a large amount of current, while when writing only one byte much smaller amount of current is needed as compared with the current used for erasing all bits. The number of bits to be written/erased is clearly shown in the instruction and does not have large variations. Thus, the required amount of current can be easily determined when the instruction is interpreted.

The determination result is used as an internal control signal of the oscillation circuit, so that when much current is required, the frequency for the booster circuit is multiplied. The charge pump circuit type booster circuit 1 as explained by using FIG. 18, boosts the voltage by transferring electric charges, so that boosting insufficiency is caused when the excessive current is consumed in the chip. On the contrary, when electric charges are transferred at a rate higher than the rate of current consumption, the voltage is continuously increased to result problems. Therefore, the configuration is very effective in which the amount of current to be consumed is estimated by the instruction decoder 45, so as to make it possible to change the frequency of the boosting clock of which the frequency multiplier section 20 generates.

Meanwhile, in the same manner of the first through sixth embodiments, it is effective to make the MOS transistors forming the inverters which are succeedingly connected to the inverters to supply the signals to the frequency multiplier circuit 20 have a low W×L especially a short L in comparison with the size of the MOS transistors of other inverters.

### Eighth Embodiment

Next, an oscillation circuit according to an eighth embodiment is explained with reference to FIG. 13 and FIG. 14. The eighth embodiment is configured so as to generate a clock having a frequency four times the frequency of the oscillation output of the ring oscillator. In FIG. 13, an oscillator 5 having a multiplied output is provided with a ring oscillator 10 which has an odd number of stages of inverters 11 to 15 and a buffer 9, and with a frequency multiplier section 20. The frequency multiplier section 20 is provided with a first exclusive OR circuit 21 which calculates exclusive OR of two signals taken from a node a and a node b, a second exclusive OR circuit 22 which calculates exclusive OR of two signals taken from a node d and a node e, and a third exclusive OR circuit 23 which calculates exclusive OR of two signals taken from an output node c of the first exclusive OR circuit 21 and an output node f of the second exclusive OR circuit 22.

The internal signals of the oscillation circuit 5 shown in FIG. 13 exhibit waveforms as shown in FIG. 14. Generally, the line-up of memory is based upon a power of two, so that the oscillation circuit 5 configured in this way can be applied to the case where a four-multiple frequency needs to be formed. Further, the oscillation circuit 5 can also be applied to the fourth embodiment to the sixth embodiment, and makes it possible to more finely perform the control described in these embodiments. Incidentally, the output waveform c of the first exclusive OR circuit 21 and the output waveform f of the second exclusive OR circuit 22 are formed into a clock having a doubled frequency, and hence, a configuration which makes it possible to separately take out the doubled clock, is also conceivable.

Meanwhile, in the same manner of the first through seventh embodiments, it is effective to make the MOS transistors forming the inverters 11, 12, 13 and 14 have a low W×L especially a short L in comparison with the size of the MOS transistor of the inverter 15.

### Ninth Embodiment

Next, an oscillation circuit according to a ninth embodiment which is capable of generating an eight-multiple clock is explained by using FIG. 15 and FIG. 16. In FIG. 15, an oscillation circuit 5 according to the ninth embodiment is provided with a ring oscillator 10 and a frequency multiplier section 20. The ring oscillator 10 is provided with a first to ninth inverters 11, 12, 13, 14, 15, 16, 17, 18, 19, and a buffer 9. An output of the ninth inverter 19 that appears at a node a is outputted as a clock of the ring oscillator via the buffer 9. The frequency multiplier section 20 is provided with a first to seventh exclusive OR circuits 21, 22, 23, 24, 25, 26, 27. Exclusive OR of the output of the ninth inverter 19 at the final stage and the output of the fourth inverter 24 at the approximately intermediate stage is calculated by the first exclusive OR circuit 21. Hereafter, the outputs of respective nodes d, e, h, i, k, l are calculated by the second to fourth exclusive OR circuits 22, 23, 24. The outputs c, f of the first and second exclusive OR circuits 21, 22 are calculated by the fifth exclusive OR circuit 25, the outputs j, m of the third and fourth exclusive OR circuits 23, 24 are calculated by the sixth exclusive OR circuit 26, and the outputs g, n of the fifth and sixth exclusive OR circuits 25, 26 are calculated by the seventh exclusive OR circuit 27. The waveforms of the respective nodes are shown in FIG. 16(A) to FIG. 16(O), and finally, the eight-multiple clock as shown in FIG. 16(O) can be obtained.

As shown in FIG. 16(A) to FIG. 16(O), the waveforms of the respective nodes h, d, k, b, i, e, l, a of the first to seventh inverters 11 to 17 and the ninth inverter 19, are different from the exclusive OR output waveforms c, f, g, j, m, n, o, respectively. Thus, as shown in the lower right in FIG. 15, it is also possible to take out a clock with a desired waveform to boost a voltage in the booster circuit 1 shown in FIG. 2, and then to supply the boosted voltage to a desired component of the EEPROM chip 50.

According to the oscillation circuit having multiplied outputs for generating the eight-multiple clock as shown in FIG. 15, it is possible to perform fine control operation of the boosted voltage by utilizing the fact that the frequency switching operation can be performed at high speed. By alternately switching the normal frequency operation and the multiplied frequency operation, it is also possible to set the boosted voltage to an intermediate voltage between the voltage at the normal operation and the voltage at the multiplied frequency operation. Further, the boosted voltage is increased by making the time period of the multiplied frequency operation longer, while the boosted voltage is reduced by making the time period of multiplied frequency operation shorter. Therefore, it is possible to optimally perform the voltage control by adjusting a ratio between the time period of the normal frequency operation and the time period of the multiplied frequency operation. At this time, the boosted voltage varies due to the switching of the oscillation frequency. However, since the booster circuit and the memory cell have a corresponding capacitance if the frequency can be switched fast and frequently, the influence of the switching operation upon the oscillation frequency can be eliminated. Therefore, according to the configuration as described in the ninth embodiment which enables clock outputs having many multiplied frequencies to be supplied, it is possible to make the boosted voltage hardly influenced by the switching of the oscillation frequency.

A further advantage according to the ninth embodiment is that the control of the oscillation frequency can be digitally performed and thereby the boosting operation can also be digitally performed. On the other hand, there is a case where the amount or change of the necessary tunnel current may also be predicted in advance. For example, such case includes a case where the number of bits to be written/erased is changed on the basis of an instruction. The nonvolatile memory, as represented by the EEPROM 50, which performs writing/erasing operation by using the tunnel current, needs a very long time period for performing the writing/erasing operation in comparison with the other operations. Therefore, there are many nonvolatile memories provided with an instruction for erasing/writing all bits, and an instruction referred to as “page” for writing a fixed amount of data at a time.

On the other hand, in the nonvolatile memory, the operation per byte or per 16 bits is also performed similarly to the normal memory. The number of operated bits is not completely proportional to the amount of consumed current because of the influence of the leakage current and the like. However, the amount of consumed current increases as the number of operation bits increases. As already described, both insufficient and excessive boosting capabilities are not preferred, and hence the boosting capability is preferably changed in accordance with the number of operation bits. The number of operation bits is digitally determined on the basis of a number obtained by the instruction decoding. According to the above described embodiment, the changing of the frequency of the oscillation output and of the capability of the boosting circuit which uses the oscillation output, can be digitally performed and directly controlled on the basis of a signal obtained as the result of the instruction decoding.

According to the ninth embodiment as shown in FIG. 15, an eight-multiple clock can be generated, and thereby it is possible to perform finer control as compared with the first to eighth embodiments in which two-multiple and four-multiple clocks are used. That is, in the two-multiple clock, only the two-multiple output c having two periods during one period which is the same as that of the ring oscillator output at the node a, is outputted as shown in FIG. 5(C), and in the four-multiple clock, only the four-multiple output g having four periods during one period of the ring oscillator output, is outputted as shown in FIG. 14(G). On the other hand, in the eight-multiple clock according to the ninth embodiment, it is possible to generate the eight-multiple output o having eight periods during one period which is the same as that of the ring oscillator output as shown in FIG. 16(O), and hence, to provide a peculiar effect that a clock with finer precision can be supplied.

### Tenth Embodiment

In the EEPROM having a floating gate, a memory is held by injecting electric charges into the floating gate through the tunnel oxide film by a high voltage. At this time, when the voltage difference between both sides which sandwich the tunnel oxide film is too small, the writing (memorization) of data is not performed, but when the voltage difference is too large, deterioration of the tunnel oxide film is accelerated.

In the floating gate, as the name indicates, portions other than the tunnel oxide film are completely electrically insulated so as to form a capacitor. From the fact that electric charges accumulated in the capacitor generates a voltage, it is seen that when electric charges are injected into the floating gate, the voltage difference between the respective side portions sandwiching the tunnel oxide film is reduced. This indicates that when a voltage is applied to the tunnel oxide film at a stroke from the beginning, the voltage difference between the both side portions sandwiching the tunnel oxide film becomes too large to cause a stress to be applied to the tunnel oxide film, while when time elapses, the voltage difference is reduced so as to make the writing dull. As a method to avoid this phenomenon, it is conceivable to gradually increase the high voltage applied at the time of writing with the lapse of time.

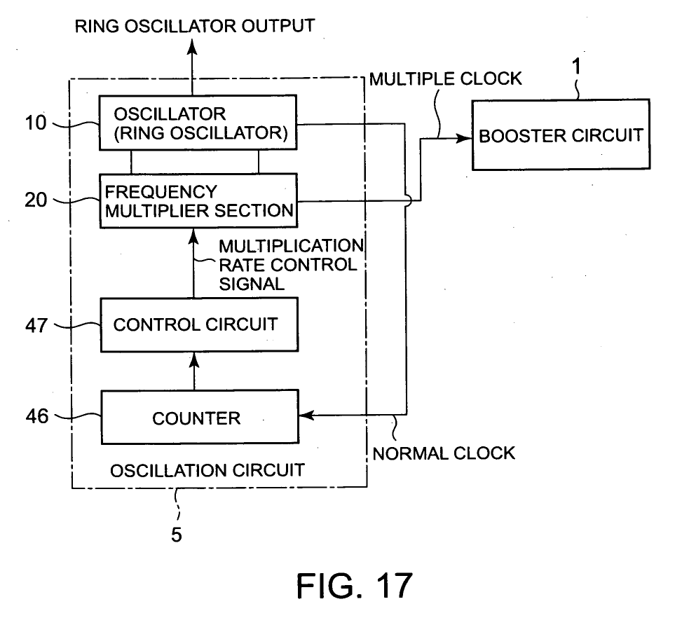

An oscillation circuit 5 according to a tenth embodiment as shown in FIG. 17 is provided with a ring oscillator 10 and a frequency multiplier section 20, and the frequency multiplier section 20 supplies a multiplied clock to a booster 1. The frequency multiplier section 20 also outputs a normal clock to a counter 46. The counter 46 measures the lapse of time by counting the normal frequency of the normal clock, and outputs the measured result to a control circuit 47. The control circuit 47 outputs a multiplication rate control signal for increasing the multiplication rate of multiplied output, to the frequency multiplier section 20 of the oscillation circuit, as the time counted by the counter 46 elapses.

The frequency multiplier section 20 generates multiplied clocks having oscillation frequencies multiplied such as at one, two, four, eight times, on the basis of the multiplication rate control signal outputted from the control circuit 47, and supplies them to a booster circuit. In the booster circuit 1, when the oscillation frequency of the inputted clock is increased, the boosted voltage is made to be increased under significantly wide conditions, so that the generated voltage can be increased as the time elapses.

According to the tenth embodiment, it is possible to effectively utilize both of the features that the basic oscillation of the ring oscillator output can be outputted, and that the multiplication rate can also be instantly and easily changed, as a result of which an effect peculiar to this embodiment can be obtained in relation to the generation of particularly stable multiplied clocks. Note that as a specific configuration of the frequency multiplier section 20 according to the tenth embodiment, it is possible to consider a configuration in which an exclusive OR device that is formed by combining the exclusive OR circuit 21 shown in FIG. 7 and the AND gate 43 is combined with the circuit shown in FIG. 13 that is capable of outputting four-multiple clock, and a configuration in which the exclusive OR device is combined with the circuit shown in FIG. 15 that is capable of outputting an eight-multiple clock, and the like.

Meanwhile, in the same manner of the first through ninth embodiments, it is effective to make the MOS transistors forming the inverters which are succeedingly connected to the inverters to supply the signals to the ring oscillator 10 to the frequency multiplier circuit 20 have a low W×L especially a short L in comparison with the size of the MOS transistors of other inverters.

### Eleventh Embodiment

Further, even though the drawing is omitted, it is possible apply a signal processing method of an eleventh embodiment in the oscillation circuit according to the first through tenth. embodiments.

A method of the eleventh embodiment for processing signals in the oscillation circuit according to the first through tenth embodiments, includes a ring oscillator configured to have multiple of inverters in which an output of the final stage inverter is an input of the first stage inverter and outputs the output of the final stage inverter as an output of the ring oscillator, and a frequency multiplier section configured to output as a multiplied output after a logic operation of some signals taken out from some inverter in the multiple of inverters.

The method of processing signals in the oscillation circuit according to the first through tenth embodiments, the method includes forming a ring oscillator constructed with the multiple of inverters from at least an odd number of stages of inverters, taking out at least two outputs from two stages of the inverters in the ring oscillators, supplying at least two outputs of two stages of the inverters to the frequency multiple section, operating an exclusive OR of two signals in a first logic circuit constructing the frequency multiple section so as to output at lease two times frequency clock, and operating an exclusive OR of two signals in a second through n-th (n is positive integer) logic circuits constructing the frequency multiple section as required, so as to output four times, m times (m is power of 2) frequency clock as multiplied frequency signals.

1. An oscillation circuit, comprising:
a ring oscillator configured to have at least an odd number of stages of inverters; and
a frequency multiplier section configured to output as a multiplied output, an exclusive OR of signals taken out from the inverters at least at two stages of the ring oscillator.

2. The oscillation circuit according to claim 1, wherein
the frequency multiplier section comprises a logic circuit configured to operate the exclusive OR of the signals taken out from at least two stages of arbitrary inverters.

3. The oscillation circuit according to claim 2, wherein
the ring oscillator comprises a plurality of inverters including the odd number of stages of inverters, and a buffer configured to input an output of a final stage of inverter to output as an output of the ring oscillator.

4. The oscillator circuit according to claim 3, wherein
the ring oscillator supplies to the frequency multiplier section, two outputs of the final stage of inverter and substantially intermediate stage of inverter, and
the frequency multiplier section outputs as the multiplied output, the exclusive OR of the signals taken out from at least two outputs of the final stage of inverter and substantially intermediate stage of inverter.

5. The oscillator circuit according to claim 4, wherein
the frequency multiplier section output a two times frequency clock which is operated as the exclusive OR of the signals taken out from the final stage of inverter and substantially intermediate stage of inverter.

6. The oscillator circuit according to claim 2, wherein
the frequency multiplier section comprises an exclusive OR circuit configured to input a control signal and the signals taken out from the two stages of arbitrary inverters, and to output anyone of the two signals by the control signal.

7. The oscillator circuit according to claim 6, wherein
the frequency multiplier section further comprises a voltage detecting circuit configured to output the control signal on the basis of a boosted voltage which is generated using the multiplied clock supplied from the frequency multiplied section.

8. The oscillator circuit according to claim 6, wherein
the frequency multiplier section comprises a first logic circuit configured to input a first control signal and anyone of the signals as outputs taken out from the two stages of inverters and to output anyone of the signals on the basis of the first control signal, a second logic circuit configured to input a second control signal and the other of the two signals as outputs taken out from the two stages of inverters and to output anyone of the signals on the basis of the second control signal, and a third logic circuit configured to input an output of the first logic circuit and an output of the second logic circuit and to output an exclusive OR signal of two outputs of the first and second logic circuits.

9. The oscillator circuit according to claim 8, wherein
the frequency multiplier section further comprises a voltage detecting circuit configured to output the control signal on the basis of a boosted voltage which is generated using the multiplied clock supplied from the frequency multiplied section.

10. The oscillator circuit according to claim 2, further comprising: a first conductive type transistors configured to provide for a high voltage side power source for the odd number of inverters constructing the ring oscillator, a first bias circuit configured to supply a bias signal to gates of the first conductive type transistors, a second conductive type transistors configured to provide for a low voltage side power source for the odd number of inverters constructing the ring oscillator, and a second bias circuit configured to supply a bias signal to gates of the second conductive type transistors.

11. The oscillator circuit according to claim 2, wherein
the ring oscillator comprises five inverters including first through fifth stage inverters, and the frequency multiplier section comprises a first logic circuit and a second logic circuit,
the first logic circuit is configured to input two outputs taken out from the fifth stage inverter and an intermediate stage inverter, respectively, and to operate an exclusive OR of the two outputs of the fifth stage inverter and the intermediate stage inverter to output a first two times frequency clock, and
the second logic circuit is configured to input two outputs taken out from the first stage inverter and any of the third and fourth stage inverters, and to operate an exclusive OR of the two outputs of the first stage inverter and any of the third and fourth stage inverters to output a second two times frequency clock.

12. The oscillator circuit according to claim 11, wherein
the frequency multiplier section further comprises a third logic circuit configured to operate an exclusive OR of the first and second two times frequency clocks to output four times frequency clock.

13. The oscillator circuit according to claim 2, wherein
the ring oscillator comprises nine inverters including first through ninth stage inverters, and the frequency multiplier section comprises first through fourth logic circuits,
the first logic circuit is configured to input two outputs taken out from the ninth stage inverter and a fourth stage inverter, respectively, and to operate an exclusive OR of the two outputs of the ninth stage inverter and the fourth stage inverter to output a first two times frequency clock,
the second logic circuit is configured to input two outputs taken out from the second stage inverter and a sixth stage inverter, respectively, and to operate an exclusive OR of the two outputs of the second stage inverter and the sixth stage inverter to output a second two times frequency clock,
the third logic circuit is configured to input two outputs taken out from the first stage inverter and a fifth stage inverter, respectively, and to operate an exclusive OR of the two outputs of the first stage inverter and the fifth stage inverter to output a third two times frequency clock, and
the fourth logic circuit is configured to input two outputs taken out from the third stage inverter and any of the seventh and eighth stage inverters, and to operate an exclusive OR of the two outputs of the third stage inverter and any of the seventh and eighth stage inverters to output a fourth two times frequency clock.

14. The oscillation circuit according to claim 13, wherein
the frequency multiplier section further comprises a fifth logic circuit configured to operate an exclusive OR of the first two times frequency clock and the second two times frequency clock to output a first four times frequency clock, a sixth logic circuit configured to operate an exclusive OR of the third two times frequency clock and the fourth two times frequency clock to output a second four times frequency clock, a seventh logic circuit configured to operate an exclusive OR of the first four times frequency clock and the second four times frequency clock to output a eight times frequency clock.

15. The oscillation circuit according to claim 2, wherein
the frequency multiplier section comprises anyone of a plurality of first logic circuits configured to output a plurality of two times frequency clocks each by at least one exclusive OR circuit, respectively, a plurality of second logic circuits configured to output first and second two timed frequency clocks each by three exclusive OR circuits, respectively, and a third logic circuit configured to output eight times frequency clock by seven exclusive OR circuits.

16. The oscillation circuit according to claim 1, wherein
the ring oscillator comprises a MOS transistor forming an inverter which is connected with a signal line taking out a signal to be supplied to the frequency multiplier section, the MOS transistor which is configured to have a low product (W×L) of width (W) and length (L) in comparison with MOS transistors of other inverters.

17. The oscillation circuit according to claim 16, wherein
the ring oscillator comprises a MOS transistor forming an inverter which is connected with a signal line taking out a signal to be supplied to the frequency multiplier section, the MOS transistor which is configured to have a short length (L) in comparison with MOS transistors of other inverters.

18. The oscillation circuit according to claim 17, wherein
when the ring oscillator supplies two outputs of a final stage inverter and substantially intermediate stage inverter to the frequency multiplier section, MOS transistors respectively constructing a first stage inverter and next stage of the intermediate stage are configured to have a low product (W×L) of width (W) and length (L) and a short length (L) in comparison with MOS transistors of other inverters.

19. The oscillation according to claim 17, wherein
the ring oscillator comprises at least five inverters including first through fifth stage inverters, and the frequency multiplier section comprises a first logic circuit configured to input two outputs taken out from the fifth inverter and intermediate stage inverter, and a second logic circuit configured to input two outputs taken out from the first inverter and anyone of the third and fourth stage inverters, and
MOS transistors constructing the first stage, the next stage of the intermediate stage, second stage, fourth stage or fifth stage inverter are configured to have a low product (W×L) of width (W) and length (L) and a short length (L) in comparison with MOS transistors of other inverters.

20. A method of processing signals in the oscillation circuit according to claim 1, the method comprising:
forming a ring oscillator constructed with the multiple of inverters from at least an odd number of stages of inverters;
taking out at least two outputs from two stages of the inverters in the ring oscillators;
supplying at least two outputs of two stages of the inverters to the frequency multiple section;
operating an exclusive OR of two signals in a first logic circuit constructing the frequency multiple section so as to output at lease two times frequency clock; and
operating an exclusive OR of two signals in a second through n-th (n is positive integer) logic circuits constructing the frequency multiple section as required, so as to output four times, m times (m is power of 2) frequency clock as multiplied frequency signals.
